(19) United States
(12) Patent Application Publication
(10) Pub. No.: US 2025/0282678 A1
(43) Pub. Date: Sep. 11, 2025

(54) TRANSPARENT SUBSTRATE PROVIDED WITH A FUNCTIONAL STACK OF THIN LAYERS

(71) Applicant: SAINT-GOBAIN GLASS FRANCE, COURBEVOIE (FR)

(72) Inventors: Denis GUIMARD, AUBERVILLIERS (FR); Romain HIVET, AUBERVILLIERS (FR)

(21) Appl. No.: 18/860,318

(22) PCT Filed: Apr. 26, 2023
(86) PCT No.: PCT/EP2023/061038

§ 371 Date: Oct. 25, 2024

(30) Foreign Application Priority Data
Apr. 28, 2022 (FR) FR2203984

(51) Int. Cl. C03C 17/34; B32B 17/10; C23C 14/00; C23C 14/08; C23C 14/35

(52) U.S. Cl. CPC C03C 17/3435; B32B 17/10036; B32B 17/10211; C23C 14/0036; C23C 14/083; C23C 14/352; B32B 2419/00; B32B 2605/00; C03C 2218/155; C03C 2218/156

(57) ABSTRACT

A transparent substrate provided on one of its main surfaces with a stack of thin layers, the stack being made up of the following layers from the substrate: a first dielectric module of one or more thin layers; a titanium nitride-based layer; a second dielectric module of one or more thin layers; wherein the first dielectric module and/or the second dielectric module comprises from the substrate: a first thin layer based on nitride; a tungsten oxide-based absorbent layer; a second nitride-based thin layer; the tungsten oxide including at least one doping element selected from group 1 chemical elements according to the IUPAC nomenclature.

### TECHNICAL FIELD

The invention relates to a transparent substrate provided with a functional stack of thin layers.

### TECHNICAL BACKGROUND

Functional stacks of thin layers are commonly used to provide functions of thermal insulation and/or solar protection to glazings equipping buildings. They aim in particular to reduce the air-conditioning effort and/or to reduce excessive overheating (so-called “solar control” glazings) and/or to reduce the amount of energy dissipated to the outside (so-called “low-emission” glazings).

Solar control functions are desired for the glazings capable of being exposed to high sunshine levels. The capacity of a glazing to limit the amount of light energy transmitted is defined by the solar factor, g, which is the ratio of the total energy transmitted through the glazed surface or the interior glazing to the incident solar energy. The lower the solar factor, g value, the better the protection against solar radiation.

EP 0 239 280 A2 [GORDON ROY GERALD] Sep. 30, 1987 describes a transparent glass substrate provided with a stack of thin layers comprising, starting from the substrate, a first layer of fluorine-doped tin oxide, a layer of titanium nitride and a layer of tin oxide. Stacking provides solar control properties with reduced light reflection and coloration.

WO 2018/129135 A1 [GUARDIAN GLASS LLC [US]] Jul. 12, 2018 describes a transparent glass substrate provided with a thin-film stack comprising three silicon nitride thin films with two infrared radiation-reflecting titanium nitride thin films sandwiched in between. The stacking confers solar control properties with reduced red color in reflection, maintained chemical and mechanical durability and low emissivity.

WO 2020/128327 A1 [SAINT GOBAIN [FR]] Jun. 25, 2020 also describes a transparent glass substrate with a thin-film stack comprising three silicon nitride thin films, with two infrared-reflective titanium nitride thin films sandwiched between them. Stacking confers solar control and external invisibility properties, so that building occupants have little or no visibility from the outside. In the La*b* system, the stack also has a reflection coefficient a* of between 10 and −10.

WO 2021/170959 A1 [SAINT GOBAIN [FR]] Sep. 2, 2021 describes a transparent glass substrate provided with a stack comprising two dielectric modules of layers between which are inserted a thin layer based on titanium nitride reflecting infrared radiation and a metallic intermediate layer based on silicon, aluminum, titanium or their mixture. The stack provides solar control properties with light transmission of over 30% and emissivity of less than 50%. The stack also has a certain chemical and mechanical durability when directly exposed.

JP 2010180449 A [SUMITOMO METAL MINING CO [JP]] Aug. 19, 2010 describes a layer based on tungsten oxide deposited by sputtering using a tungsten oxide target comprising chemical elements selected from hydrogen, alkali metals, alkaline earth metals and rare earth metals. The layer has a “solar control” function by virtue of its high absorption of near-infrared radiation.

EP 3686312 A1 [SUMITOMO METAL MINING CO [JP]] Jul. 29, 2020 describes a layer based on tungsten oxide doped with cesium, and a method for depositing such a layer by sputtering. The layer has a “solar control” function particularly by virtue of its high absorption of infrared radiation.

### SUMMARY OF THE INVENTION

### Technical Problem

A functional stack is called a functional stack suitable for such applications when it meets a triple requirement: a high light transmission, a low solar factor value and a low emissivity value. A functional stack is therefore suitable when it has a selectivity value, s, defined as the ratio of the light transmission to the high solar factor and a low emissivity.

The prior art solutions consisting of using, in the functional stack, only infrared radiation absorbent layers as functional layers, are not suitable because they have a higher emissivity, incompatible for example with applications on the residential market.

On the other hand, for applications in the residential market, particularly for use as single glazing, a functional stack must have a certain chemical and mechanical durability, especially when in contact with the outside environment.

There also remains a need to improve the energy performance of the stacks of thin layers that do not comprise any functional metal layers reflecting infrared radiation, in particular that do not comprise silver-based functional metal layers.

More specifically, there remains a need for a stack with at least one infrared radiation-reflecting titanium nitride-based layer, which has high selectivity and suitable overall energy performance, particularly with regard to emissivity.

### Solution to the Technical Problem

A first aspect of the invention relates to a transparent substrate as disclosed in claim 1, the dependent claims being advantageous embodiments. The transparent substrate is provided on one of its main surfaces with a stack of thin layers, said stack consists of the following layers from the substrate:
a first dielectric module of one or more thin layers;
a titanium nitride-based layer;
a second dielectric module of one or more thin layers;
   wherein the first dielectric module and/or the second dielectric module comprises from the substrate:
a first thin layer based on nitride;
a tungsten oxide-based absorbent layer;
a second nitride-based thin layer;
said tungsten oxide comprises at least one doping element selected from group 1 chemical elements according to the IUPAC nomenclature.

Advantageous embodiments are described in the detailed description.

According to a second aspect of the invention, a single glazing and a laminated glazing are provided comprising a transparent substrate according to the first aspect of the invention.

According to a third aspect of the invention, a method is provided such that the manufacture of a transparent substrate according to the first aspect of the invention.

### Advantages of the Invention

A notable advantage of a glazing comprising a transparent substrate according to the invention is a gain of up to more than 10% on the selectivity while maintaining a sufficient light transmission level, greater than 65% in single glazing applications, and an emissivity of 5 W/m²·K, or even less.

Another advantage of the invention is that the functional stack has better mechanical and chemical durability, in particular by the encapsulation of the tungsten oxide layer by nitride-based layers, as detailed in some embodiments.

### BRIEF DESCRIPTION OF THE DRAWINGS

FIG. 1 is a schematic depiction of one embodiment of the first aspect of the invention.

FIG. 2 is a schematic depiction of a second embodiment of the first aspect of the invention.

### DETAILED DESCRIPTION OF EMBODIMENTS

The following definitions and conventions are used.

The term “above”, respectively “below”, describing the position of a layer or of an assembly of layers and defined in relation to the position of another layer or another assembly, means that said layer or said assembly of layers is closer to, respectively further from, the substrate. These two terms, “above” and “below”, do not at all mean that the layer or the assembly of layers which they describe and the other layer or the other assembly with respect to which they are defined are in contact. They do not exclude the presence of other intermediate layers between these two layers. The expression “in contact” is explicitly used to indicate that no other layer is positioned between them.

Without any fuller information or qualifier, the term “thickness” used for a layer corresponds to the physical, real or geometric thickness, e, of said layer. It is expressed in nanometers.

The expression “dielectric module” denotes one or more layers in contact with one another forming an assembly of layers which is dielectric overall, that is to say that it does not have the functions of a functional metal layer. If the dielectric module comprises several layers, they may themselves be dielectric. The physical, real or geometric thickness, of a dielectric module of layers, corresponds to the sum of the physical, real or geometric thicknesses, of each of the layers which constitute it.

In the present description, the expressions “a layer of” or “a layer based on”, used to describe a material or a layer as to what it contains, are used equivalently. They mean that the mass fraction of the constituent that it comprises is at least 50%, in particular at least 70%, preferably at least 90%. In particular, the presence of minority or doping elements is not excluded.

The term “transparent” used to describe a substrate means that the substrate is preferably colorless, non-opaque and non-translucent in order to minimize the absorption of the light and thus retain a maximum light transmission in the visible electromagnetic spectrum.

In the case of a building glazing, particularly a single glazing, “Light transmittance” is understood to mean the light transmittance, denoted TL, as defined and measured in section 4.2 of the standard EN 410.

In the case of a building glazing, the light transmission in the visible spectrum, TL, the solar factor, g, and the selectivity, s, the internal reflection, Rint, and the external reflection, Rext, in the visible spectrum are defined, thus measured and calculated in conformity with the standards EN 410, ISO 9050 and ISO 10292 in the case of a glazing.

In the case of a laminated glazing, “thermal transmission factor,” Ug, is understood to mean the thermal transmission factor as defined according to standards EN 673.

In accordance with the nomenclature of IUPAC, group 1 of the chemical elements comprises hydrogen and alkaline elements, that is, lithium, sodium, potassium, rubidium, cesium and francium.

The expressions “optical refraction index” and “optical extinction coefficient”, are understood as the optical refraction index, n, and optical extinction coefficient, k, as defined in the technical field, in particular according to the Forouhi & Bloomer described in the Forouhi & Bloomer, Handbook of Optical Constants of Solids II, Palik, E. D. (ed.), Academic Press, 1991, Chapter 7.

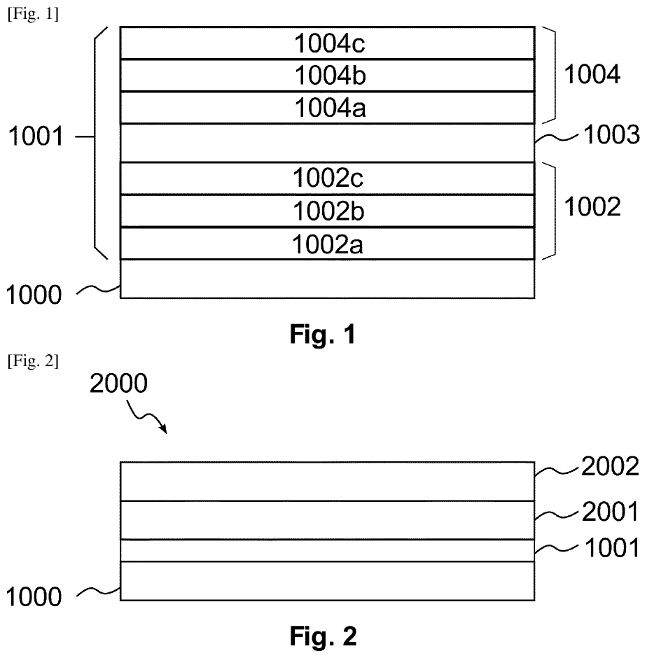

According to a first aspect of the invention, with reference to FIG. 1, there is provided a transparent substrate 1000 provided on one of its major surfaces with a stack 1001 of thin layers, said stack 1001 consists of the following layers from the substrate:
a first dielectric module 1002 of one or more thin layers;
a layer 1003 based on titanium nitride;
a second dielectric module 1004 of one or more thin layers;
   wherein the first dielectric module 1002 and/or the second dielectric module 1004 comprises, starting from the substrate 1001;
a first thin layer 1002a, 1004a based on nitride;
an absorber layer 1002b, 1004b based on tungsten oxide;
a second nitride-based thin layer 1002c, 1004c;
   said tungsten oxide comprises at least one doping element selected from the chemical elements of group 1 according to the IUPAC nomenclature.

In accordance with the first aspect of the invention, the first dielectric module 1002 and/or the second dielectric module 1004 comprise a layer 1002b, 1004b of tungsten oxide. Thus, in a first embodiment, only the first dielectric module 1002 comprises a tungsten oxide layer 1002b. In a second embodiment, only the second dielectric module 1004 comprises a tungsten oxide layer 1004b. In a third embodiment, each of the dielectric modules 1002, 1004 comprises a layer 1002b, 1004b of tungsten oxide.

When the first dielectric module and the second dielectric module each comprise a tungsten oxide layer, the tungsten oxide of the two tungsten oxide layers can be of different composition.

The transparent substrate 1000 may preferably be planar. It may be organic or inorganic, rigid or flexible. In particular, it may be a mineral glass, for example a soda-lime-silica glass.

Examples of organic substrates which can advantageously be used in the implementation of the invention may be polymer materials, such as polyethylenes, polyesters, polyacrylates, polycarbonates, polyurethanes or polyamides. These polymers can be fluoropolymers.

Examples of inorganic substrates which can advantageously be employed in the invention may be sheets of inorganic glass or glass-ceramic. The glass may preferably be a glass of soda-lime-silica, borosilicate, aluminosilicate or else alumino-borosilicate type. According to a preferred embodiment of the invention, the transparent substrate 1000 is a sheet of soda-lime-silica mineral glass.

According to the invention, the stack 1001 of thin layers that do not comprise any functional metal layers reflecting infrared radiation, in particular that do not comprise silver-based functional metal layers.

Preferably, the optical refractive index of the tungsten oxide layer 1002b, 1004b is decreasing monotonically with the wavelength from a maximum value greater than 2.4 at 350 nm up to a minimum value between 600 nm and 1400 nm so that the difference between the maximum value and the minimum value is greater than 0.8, preferably greater than 1.0, or even greater than 1.4.

In other words, the value of the optical refractive index decreases monotonically by at least 0.8, preferably at least 1.0, or even at least 1.4 between a maximum value greater than 2.4 at 350 nm and a minimum value between 600 nm and 1400 nm. As an example, the optical refractive index value can decrease monotonically by at least 0.8, preferably at least 1.0, or even at least 1.4 between a maximum value greater than 2.4 at 350 nm and a minimum value less than 2.3 between 600 nm and 1400 nm, especially between 800 nm and 1100 nm.

While not particularly required to achieve the effects of the present invention, these optical refractive index values can nevertheless be advantageous for improving color neutrality in transmission and reflection.

Preferably, the optical extinction coefficient of the tungsten oxide layer 1002b, 1004b can be less than 0.2 or even 0.1 at 500 nm and less than 2 or even less than 1.5 at 1200 nm. The selectivity can thus be advantageously further increased.

The optical extinction coefficient and the optical diffraction index can vary depending on the nature and the amount of the doping element(s) selected from the elements of the group 1 according to the IUPAC nomenclature. However, it is currently difficult to establish a law of general behavior of the optical extinction coefficient and of the refractive index according to the nature and/or the quantity of the doping element(s).

According to certain particular embodiments, the tungsten oxide layer 1002b, 1004b comprises the doping element X or the doping elements X1, X2, . . . in a proportion such that the molar ratio, X/W of said element on tungsten, W, or the sum of the molar ratios of each element on tungsten (X1+X2+ . . . )/W is between 0.01 and 0.6, preferably between 0.02 and 0.03.

It was observed that these molar ratio values can advantageously make it possible to obtain the values of optical extinction coefficient and of refractive index described in the preceding embodiments while limiting the quantity of doping elements. Furthermore, a saving on the exploitation of the mineral resources for the doping elements may possibly result, as well as a reduction in costs.

According to certain embodiments, the tungsten oxide layer 1002b, 1004b comprises at least one doping element selected from hydrogen, lithium, sodium, potassium and cesium. Among the elements of group 1, these particular elements can make it possible to obtain the most optimal values of optical extinction coefficient and refractive index for the desired technical effects.

According to particularly preferred embodiments, the tungsten oxide layer 1002b, 1004b comprises cesium as a doping element, and the molar ratio of cesium to tungsten is between 0.01 and 0.4, preferably between 0.01 and 0.2. These embodiments make it possible to obtain the best performance as to the increase in selectivity, the preservation of neutral colors, and the cost savings.

According to certain advantageous embodiments, the physical thickness of the tungsten oxide layer(s) 1002b, 1004b can be between 6 nm and 350 nm, in particular between 20 nm and 250 nm, preferably between 40 nm and 200 nm. These intervals of thicknesses are sufficient to obtain the remarkable advantages of the first aspect of the invention.

According to some embodiments, the first 1002a, 1004a and second 1002c, 1004c nitride-based thin films of the first dielectric module 1002 and/or second dielectric module 1004 may be selected from aluminum nitride, silicon zirconium nitride, or silicon nitride optionally doped with aluminum, zirconium and/or boron.

In preferred embodiments, the first 1002a, 1004a and second 1002c, 1004c nitride layers of the first 1002 and second 1004 dielectric modules are based on aluminum nitride or silicon nitride.

The first 1002a, 1004a and second 1002c, 1004c nitride-based layers of the first 1002 and/or second 1004 dielectric module are located on either side of the 1002b, 1004b tungsten oxide-based layer. The tungsten oxide-based layer 1002b, 1004b is then encapsulated.

This encapsulation allows a double protection of the absorbent layer 1002b, 1004b based on tungsten oxide. On the one hand, it prevents any contamination by elements capable of diffusing into the stack from the substrate, such as in particular alkali metal or oxygen ions in the case of a mineral glass substrate. On the other hand, it makes it possible to limit, in particular during an annealing heat treatment step, the diffusion of oxygen into the stack toward the absorbent layer based on tungsten oxide from the atmosphere and/or the substrate.

By virtue of the encapsulation, the chemical composition and the degree of oxidation of the absorbent tungsten oxide layer vary little over time, or if they vary, this variation is favorable for the selectivity. Moreover, when the stack is subjected to an annealing heat treatment, the encapsulation ensures a proper level of selectivity. In use, the substrate according to the first aspect of the invention is more durable, in particular its performance is preserved over the long term.

The first dielectric module 1002 and the second dielectric module 1004 may comprise additional thin layers. In particular, these additional layers may have chemical compositions making it possible to confer particular optical properties to the substrate, for example in terms of colors or filtering of certain wavelengths of the electromagnetic spectrum. They may also confer certain mechanical and/or chemical properties, such as resistance to abrasion, delamination and/or chemical attack. These layers are generally based on oxides or oxynitrides of metals or metal alloys.

Depending on their composition and their arrangement in the stack, these additional layers can be sources of contamination of the absorbent layer based on tungsten oxide. These sources of contamination may be a diffusion of certain metal or dopant ions or else an oxygen diffusion. They may take place during the deposition of the additional layers, during optional heat treatment of the stack, or else in use.

Such contaminations can alter the absorbent layer based on tungsten oxide and are detrimental to the performance of the substrate according to the first aspect of the invention.

In preferred embodiments, the first 1002a, 1004a and second 1002c, 1004c nitride-based layers of the first 1002 and second 1004 dielectric modules are in contact with the tungsten oxide layer 1002b, 1004b.

According to particular embodiments, the first dielectric module 1002 and/or the second dielectric module 1004 are formed from the substrate 1000:
the first thin layer 1002a, 1004a based on nitride;
the absorber layer 1002b, 1004b based on tungsten oxide; and
the second nitride-based thin layer 1002c, 1004c.

When the first dielectric module 1002 and/or the second dielectric module 1004 are constituted in this way, that is, comprise only the aforementioned nitride-based layers, the risk of alteration of the tungsten oxide-based absorber layer by possible oxygen diffusion is then limited or even eliminated. The durability of the substrate according to the first aspect of the invention may then be maximal as to the desired “solar control”.

According to embodiments, the thickness of the titanium nitride layer 1003 is between 5 nm and 25 nm, preferably between 10 nm and 20 nm, the thickness of the tungsten oxide-based absorber layer(s) is between 5 and 100 nm, preferably between 10 and 50 nm, and the thicknesses of the nitride-based layers 1002a, 1004a, 1002c, 1004c of the first 1002 and second 1004 dielectric modules are between 5 nm and 100 nm, preferably between 5 nm and 50 nm.

According to a second aspect of the invention, a single glazing is provided comprising a substrate according to the first aspect of the invention. Referring to FIG. 2, also provided is a laminated glazing 2000 comprising a first transparent substrate 1000 according to the first aspect of the invention, a lamination interlayer 2001 and a second transparent substrate 2002, such that the first transparent substrate 1000 and the second transparent substrate 2002 are in adhesive contact with the lamination interlayer 2001 and the stack 1001 of thin layers of the first transparent substrate 1000 is in contact with the lamination interlayer 2001.

The lamination interlayer 2001 may consist of one or more layers of thermoplastic material. Examples of thermoplastic material are polyurethane, polycarbonate, polyvinyl butyral (PVB), polymethyl methacrylate (PMMA), ethylene vinyl acetate (EA) or an ionomer resin.

The lamination interlayer 2001 may be in the form of a multilayer film. It may also have particular functionalities such as, for example, acoustic or anti-UV properties.

Typically, the lamination interlayer 2001 comprises at least one PVB layer. Its thickness ranges from 50 μm to 4 mm. In general, it is less than 1 mm.

According to certain preferred embodiments, the laminated glazing 2000, when used as a glazing of a motor vehicle, for example as windshield, is such that the substrate 1000 according to the first aspect of the invention is located inside the vehicle. In other words, the stack is placed on face 2 of the glazing from the substrate 1000 oriented toward the interior of the vehicle, the face 1 being the face oriented towards the interior; or on face 3 of the glazing from the substrate 1000 oriented toward the exterior of the vehicle, the face 1 being the face oriented toward the exterior.

According to certain embodiments, the second substrate 2002 may be a mineral glass tinted in the mass. The tinting or coloring in the mass of a mineral glass is known and abundantly described in the technical literature. The coloring may generally be obtained by adding coloring oxide in the glass chemical composition. Examples of coloring oxides may be iron II oxide, copper oxide, chromium oxide, nickel oxide, gold oxide, manganese oxide, cobalt oxide, uranium oxide, neodymium oxide and erbium oxide. Mixtures of oxides such as copper and tin oxide, or ionic complexes, such as iron-sulfur or cadmium-sulfur complex, can also be used.

Laminated glass manufacturing processes are well known to the glass industry. By way of example, a method for manufacturing laminated glazing can be a method for laminating a laminating interlayer between two sheets of glass. The glass sheets can be preformed, for example in a curved shape using a bending process. They can also be coated with one or more thin-film coatings using any suitable thin-film deposition process.

The methods for depositing thin layers on substrates, in particular glass sheets, are methods well known in industry. By way of example, the deposition of a stack of thin layers on a glass substrate is carried out by successive depositions of each thin layer of said stack by passing the glass substrate through a succession of deposition cells suitable for depositing a given thin layer.

The deposition cells can use deposition methods such as magnetic field assisted sputtering, ion beam assisted deposition (IBAD), evaporation, chemical vapor deposition (CVD), plasma enhanced chemical vapor deposition (PECVD), low pressure chemical vapor deposition (LPCVD), etc.

The magnetic field enhanced sputtering deposition method is particularly used. The conditions for deposition of layers are widely documented in the literature, for example in patent applications WO2012/093238 A1 and WO2017/00602 A1.

According to a third aspect of the invention, a method is provided for manufacturing a substrate 1000 according to the first aspect of the invention, such that the absorbent tungsten oxide layer or layers 1002b, 1004c are deposited by a magnetron sputtering method using a tungsten oxide target doped using a chemical element chosen from the chemical elements of group 1 according to the IUPAC nomenclature.

The tungsten oxide target may in particular contain one or more doping elements in a proportions as described for the tungsten oxide layer doped in some embodiments of the first aspect of the invention.

The tungsten oxide layer 1002b, 1004b can be deposited by sputtering using the aforementioned target under a deposition atmosphere composed of 60% to 100% argon and 0% to 40% dioxygen, preferably 70% to 85% argon and 15% to 30% dioxygen.

The tungsten oxide layer 1002b, 1004b may be deposited under a pressure between 1 to 15 mTorr, preferably 3 to 10 mTorr.

Preferably, the deposition can be carried out cold, that is to say at a temperature of less than 100° C., in particular between 20° C. and 60° C., for the substrate.

The deposition can also be carried out hot, in particular at a temperature between 100° C. and 400° C.

According to particular embodiments, the substrate 1000, after deposition of the stack 1001, can undergo an annealing heat treatment. The annealing temperature may be between 450° C. and 800° C., in particular between 550° C. and 750° C., or even between 600° C. and 700° C. The annealing time may be between 5 min and 30 min, in particular between 5 min and 20 min, or even between 5 min and 10 min.

All the embodiments described, whether they relate to the first aspect or the second aspect of the invention, can be combined with one another without modification or particular adaptation. In the event that technical incompatibilities appear during the implementation of one of these combinations, it is within the scope of the person skilled in the art to be able to solve them by means of their knowledge without this requiring undue effort, in particular by implementing a research program.

### EXAMPLES

The features and advantages of the present invention are shown by the non-limiting examples disclosed hereinafter.

Two examples, E1 to E2, according to the invention, and two counterexamples CE1 and CE2 not in accordance with the invention, are described in Table 1, which indicates the composition and the thickness of the various layers expressed in nanometers. The numbers in the first two columns correspond to the references of the figures.

The layer, denoted CWO, of cesium-doped tungsten oxide. The molar ratio of cesium to tungsten in the layer is about 0.05-0.06.

| Tab. 1 | | | E1 | E2 | CE1 |
|---|---|---|---|---|---|
| | 1004 | SiN | 29 | 11 | 41 |
| | | CWO | 20 | 29 | |
| | | SiN | 5 | 5 | |
| | 1003 | TiN | 9.8 | 12.8 | 9.8 |
| | 1002 | SiN | 5 | 5 | |
| | | CWO | 9 | 10 | |
| | | SiN | 33 | 33 | 33 |
| 1000 | | glass | 6 mm | 6 mm | 6 mm |

The CE1 counter-example differs from the other examples in the absence of a tungsten oxide layer.

The stacks of thin layers of functional coatings 1004 of examples E1 to E3 and of counter-examples CE1 and CE2 were deposited by magnetic-field-assisted cathode sputtering (magnetron method) whose characteristics are widely documented in the literature, for example in patent applications WO2012/093238 and WO2017/00602.

The nature of the targets used and the deposition conditions of examples E1 to E2 and counter-example CE1 are described in table 2.

Functional coatings 1001 are deposited directly on the glass sheet 1000. This glass sheet 1000 is a 6 mm thick sheet of soda-lime-silica mineral glass. Just after deposition, the functional coatings were subjected to a heat treatment at 650° C. for 10 min.

| | | Pressure | Ar | O2 | N2 | Power |
|---|---|---|---|---|---|---|
| Tab. 2 | Target | (μbar) | (sccm) | (sccm) | sccm | (W) |
| TiN | Ti | 2 | 32 | 0 | 15 | 2500 |
| SiN | Si:Al | 5 | 7 | 0 | 14 | 2000 |
| CWO | CWO:Cs/W | 4-10 | 30-40 | 2-10 | 0 | 1300 |
| | 0.3-0.4 | | | | | |

The solar factor, g, the selectivity, s, the light transmission, TL, the light reflection on the interior face, Rint, and on the exterior face, Rext, as well as the color in transmission, on the interior face and on the exterior face, were measured for each example E1 to E2 and the counter-example CE1.

The light transmission in the visible spectrum, TL, the solar factor, g, the selectivity, s, and the internal reflection, Rint, and the external reflection, Rext, in the visible spectrum are defined, measured and calculated in conformity with the standards EN 410, ISO 9050 and/or ISO 10292.

The emissivity, Ug, is defined, measured and calculated in compliance with EN 410 and EN 12898.

The expression “color”, used to describe a transparent substrate provided with a stack, is understood to mean the color as defined in the L*a*b* CIE 1976 chromatic space according to standard ISO 11664, in particular with a D65 illuminant and a visual field of 2° or 10° for the reference observer. It is measured in accordance with said standard.

The measurements of emissivity, solar factor, selectivity, light transmission, internal reflection, external reflection, color parameters a* and b*, in transmission (a*T, b*T), in external reflection (a*Rext, b*Rext) and in internal reflection (a*Rint, b*Rint) are grouped together in Table 3.

| Tab. 3 | E1 | E2 | CE1 |
|---|---|---|---|
| g | 57.2 | 56.0 | 61.5 |
| s | 1.15 | 1.18 | 1.07 |
| TL | 66.0 | 66.0 | 66.0 |
| a*T | −3.8 | −3.6 | −1.3 |
| b*T | −3.9 | −2.7 | −2.4 |
| Rext | 12.1 | 15.8 | 15.0 |
| a*Rext | −3.7 | −5.1 | −2.1 |
| b*Rext | −0.1 | 0.0 | −2.1 |
| Rint | 7.9 | 9.6 | 12.1 |
| a*Rint | 2.0 | 2.0 | −4.0 |
| b* Rint | 6.0 | 4.1 | 6.1 |
| Ug | 5.0 | 4.8 | 5.0 |

Compared with counter-example CE1, examples E1 and E2 have a lower solar factor for the same light transmission. Their selectivity is therefore higher. The thermal transmittance of examples E1 and E2 is similar to that of the counter-example, or even slightly lower for example E1. The parameters a* and b* are close to zero in both transmission and reflection, indicating that examples E1 and E2 have a relatively neutral color in transmission and/or reflection.

Examples E1 and E2 also show lower, if not comparable, levels of internal and external reflection to counter-example CE1.

The stacks 1001 of examples E1 to E2, and of counter-example CE1 have also been used to form laminated glazings, labeled VFE1, VFE2, and VFCE1, respectively.

Functional coatings 1001 were deposited under the same conditions as above on sheets 1000 of 4 mm thick soda-lime-silica mineral glass. Just after deposition, the functional coatings were subjected to a heat treatment at 650° C. for 10 min.

Once deposition and heat treatment have been completed, each of the glass sheets 1000 with a functional coating 1001 is laminated with a lamination interlayer 2001 of 0.38 mm thick PVB and a second glass sheet 2002 of 4 mm thick soda-lime-silica mineral glass to form a laminated glazing as shown in FIG. 2.

The solar factor, g, the selectivity, s, the light transmission, TL, the light reflection on the interior face, Rint, and on the exterior face, Rext, as well as the color in transmission, on the interior face and on the exterior face, were measured for each example VFE1 to VFE2 and the counter-example VFCE1.

The light transmission in the visible spectrum, TL, the solar factor, TTS, the selectivity, s, and the internal reflection, Rint, and the external reflection, Rext, in the visible spectrum are defined, measured and calculated in conformity with the standards ISO 13837:2021.—convention A.

The thermal transmission factor, Ug, is defined, measured and calculated in accordance with standard EN 673.

The expression “color”, used to describe a transparent substrate provided with a stack, is understood to mean the color as defined in the L*a*b* CIE 1976 chromatic space according to standard ISO 11664, in particular with a D65 illuminant and a visual field of 2° or 10° for the reference observer. It is measured in accordance with said standard.

Measurements of emissivity, solar factor, selectivity, light transmission, internal reflection, external reflection, color parameters a* and b*, in transmission (a*T, b*T), external reflection (a*Rext, b*Rext) and internal reflection (a*Rint, b*Rint) are grouped together in Table 4.

| Tab. 4 | VFE1 | VFE2 | VFCE1 |
|---|---|---|---|
| g | 58.8 | 56.1 | 57.9 |
| s | 1.16 | 1.19 | 1.14 |
| TL | 68.3 | 66.5 | 66 |
| a*T | −4.0 | −4.0 | −3.4 |
| b*T | 0.0 | 0.0 | 0.0 |
| Rext | 8.1 | 12.7 | 8.0 |
| a*Rext | 0.9 | −3.6 | 0.5 |
| b*Rext | −2.3 | −0.1 | 0.0 |
| Rint | 7.2 | 7.2 | 8.1 |
| a*Rint | 1.4 | 1.9 | 0.3 |
| b*Rint | −5.0 | −6.4 | 0.5 |
| Ug | 5.6 | 5.6 | 5.6 |

Compared with counter-example VFCE1, examples VFE1 and VFE2 offer higher selectivity. The emissivity of examples E1 and E2 is similar to that of the counter-example. The parameters a* and b* are close to zero in both transmission and reflection, indicating that examples E1 and E2 have a relatively neutral color in transmission and/or reflection.

These examples very clearly show the advantages of the substrates and glazings according to the invention, namely that they have a higher selectivity, and a neutral color.

1. A transparent substrate provided on one of its main surfaces with a stack of thin layers, said stack consists of the following layers from the substrate:
a first dielectric module of one or more thin layers;
a titanium nitride-based layer;
a second dielectric module of one or more thin layers;
wherein the first dielectric module and/or the second dielectric module comprises from the substrate:
a first thin layer based on nitride;
an absorbent layer based on tungsten oxide;
a second thin layer based on nitride;
said tungsten oxide comprises at least one doping element selected from the chemical elements of group 1 according to the IUPAC nomenclature.

2. The substrate according to claim 1, wherein the tungsten oxide absorbent layer comprises doping element X or doping elements X1, X2, . . . in proportions such that a molar ratio, X/W of said element on tungsten, W, or a sum of the molar ratios of each element on tungsten (X1+X2+ . . . )/W is between 0.01 and 0.6.

3. The substrate according to claim 1, wherein the tungsten oxide absorbent layer comprises at least one doping element selected from hydrogen, lithium, sodium, potassium and cesium.

4. The substrate according to claim 3, wherein the tungsten oxide absorbent layer comprises cesium as a doping element, and a molar ratio of cesium to tungsten is between 0.01 and 0.4.

5. The substrate according to claim 1, wherein a physical thickness of the tungsten oxide absorbent layers is between 6 nm and 350 nm.

6. The substrate according to claim 1, wherein the first and second nitride-based layers of the first and second dielectric modules are based on aluminum nitride or silicon nitride.

7. The substrate according to claim 1, wherein the first and second nitride-based layers of the first and second dielectric modules are in contact with the tungsten oxide absorbent layer.

8. The substrate according to claim 1, wherein the first dielectric module and/or the second dielectric module are formed from the substrate of:
the first thin nitride-based layer;
the absorbent layer based on tungsten oxide;
the second nitride-based thin layer.

9. The transparent substrate according to claim 1, wherein a thickness of the titanium nitride layer is between 5 nm and 100 nm, a thickness of the tungsten oxide-based absorbent layer is between 5 and 100 nm, and thicknesses of the nitride-based layers of the first and second dielectric modules are between 5 nm and 100 nm.

10. A single glazing comprising a substrate according to claim 1.

11. A laminated glazing comprising a first transparent substrate according to claim 1, a lamination interlayer and a second transparent substrate, wherein the first transparent substrate and the second transparent substrate are in adhesive contact with the lamination interlayer and the stack of thin layers of the first transparent substrate is in contact with the lamination interlayer.

12. A method for manufacturing a transparent substrate according to claim 1, comprising depositing the tungsten oxide absorbent layer are deposited by a magnetron sputtering method using a tungsten oxide target doped using a chemical element chosen from the chemical elements of group 1 according to the IUPAC nomenclature.

13. The manufacturing method according to claim 12, wherein the tungsten oxide absorbent layer is deposited at a substrate temperature of less than 100° C.

14. The manufacturing method according to claim 12, wherein the tungsten oxide absorbent layer is deposited in a deposition atmosphere composed of 60% to 100% argon and 0% to 40% dioxygen.

15. The manufacturing method according to claim 12, wherein the tungsten oxide absorbent layer is deposited at a pressure of between 1 and 15 mTorr.

16. The substrate according to claim 2, wherein the sum of the molar ratios of each element on tungsten (X1+X2+ . . . )/W is between 0.02 and 0.3.

17. The substrate according to claim 4, wherein the molar ratio of cesium to tungsten is between 0.01 and 0.2.

18. The substrate according to claim 5, wherein the physical thickness of the tungsten oxide absorbent layer is between 20 nm and 250 nm.

19. The transparent substrate according to claim 9, wherein the thickness of the titanium nitride layer is between 10 nm and 50 nm, the thickness of the tungsten oxide-based absorbent layer is between 10 and 50 nm, and the thicknesses of the nitride-based layers of the first and second dielectric modules are between 5 nm and 50 nm.

20. The manufacturing method according to claim 13, wherein the substrate temperature is between 20° C. and 60° C.
